(19) United States
(12) Patent Application Publication
(10) Pub. No.: US 2024/0018390 A1
(43) Pub. Date: Jan. 18, 2024

(54) POLISHING COMPOSITION

(71) Applicant: FUJIMI INCORPORATED, Aichi (JP)

(72) Inventors: Yukinobu YOSHIZAKI, Aici (JP); Hirofumi Ikawa, Aichi (JP)

(21) Appl. No.: 18/373,514

(22) Filed: Sep. 27, 2023

Related U.S. Application Data
(63) Continuation of application No. 17/412,919, filed on Aug. 26, 2021.

(30) Foreign Application Priority Data
Sep. 23, 2020 (JP) 2020-158993

(51) Int. Cl. C09G 1/02; H01L 21/304; H01L 21/02; C09K 13/00; C23F 3/00

(52) U.S. Cl. CPC C09G 1/02; H01L 21/304; H01L 21/02024; C09K 13/00; C23F 3/00; B24D 3/346

(57) ABSTRACT

Provided is a polishing composition in which a polishing speed of silicon germanium is sufficiently high and a selection ratio of the polishing speed of silicon germanium is sufficiently high. A polishing composition includes: abrasive grains; an inorganic salt; and an oxidizing agent, in which the number of silanol groups per unit surface area of the abrasive grains is more than 0/nm² and 2.0/nm² or less, and a pH of the polishing composition is 6.0 or more.

### BACKGROUND

### 1. Technical Field

The present invention relates to a polishing composition.

### 2. Description of Related Arts

As one of techniques for reducing power consumption and improving performance (operation characteristics) of a transistor, a channel using a high mobility material having higher carrier mobility than Si (hereinafter, also simply referred to as “high mobility material”) has been studied. In a channel produced using such a high mobility material and having improved carrier transport characteristics, it is possible to increase a drain current flowing when a specified gate voltage is applied. This provides an advantage that the voltage from a power source can be decreased while a sufficiently high drain current is obtained. This advantage leads to higher performance of a MOSFET (metal oxide semiconductor field-effect transistor) at a low electric power.

As the high mobility material, application of a Group III-V compound, a Group IV compound, Ge (germanium), graphene composed only of C (carbon), and the like is expected. Particularly, Group III-V compounds containing As, Group IV compounds containing Ge, and the like have been actively studied.

The channel using the high mobility material can be formed by polishing an object to be polished having a portion containing a high mobility material (hereinafter, also referred to as “high mobility material portion”) and a portion containing a silicon material (hereinafter, also referred to as “silicon material portion”), such as silicon germanium (SiGe). For example, JP 2018-506176 A (US 2017/0369743 A) discloses a polishing composition used for polishing a substrate containing germanium.

### SUMMARY

Recently, a substrate containing both silicon germanium and another material such as silicon nitride (SiN) or silicon oxide (SiO₂) has been used as a semiconductor substrate. In such a substrate, there is a new demand to selectively polish silicon germanium with respect to the other material while silicon germanium is polished at a high polishing speed. No consideration has been heretofore made on such a demand.

Therefore, an object of the present invention is to provide a polishing composition in which a polishing speed of silicon germanium is sufficiently high and a selection ratio of the polishing speed of silicon germanium is sufficiently high.

The inventors have carried out a diligent study to solve the new problems described above. As a result, the inventors have found that the above problems are solved by a polishing composition including: abrasive grains; an inorganic salt; and an oxidizing agent, in which the number of silanol groups per unit surface area of the abrasive grains is more than 0/nm² and 2.0/nm² or less, and a pH of the polishing composition is 6.0 or more, and have completed the present invention.

### DETAILED DESCRIPTION

One aspect of the present invention is a polishing composition including: abrasive grains; an inorganic salt; and an oxidizing agent, in which the number of silanol groups per unit surface area of the abrasive grains is more than 0/nm² and 2.0/nm² or less, and a pH of the polishing composition is 6.0 or more. According to the polishing composition of the present embodiment, it is possible sufficiently increase a polishing speed of silicon germanium, and it is possible sufficiently increase a selection ratio of the polishing speed of silicon germanium, i.e., a selection ratio of the polishing speed of silicon germanium to the polishing speed of another material (e.g., silicon nitride (SiN) or silicon oxide (SiO₂)).

The mechanism by which the effects of the present invention as described above can be obtained is considered as follows. However, the following mechanism is merely presumption, and the scope of the present invention is not limited by this mechanism.

The number of silanol groups per unit surface area of the abrasive grains is more than 0/nm² and 2.0/nm² or less, whereby the hydrophobicity of the surface of the abrasive grains is enhanced. As a result, it is considered that it is possible to improve the polishing speed of silicon germanium oxidized by the action of the oxidizing agent.

Further, since the number of silanol groups per unit surface area of the abrasive grains is low, the amount of bound water present between abrasive grains and a surface of a silicon-germanium film is reduced. Therefore, it is considered that the abrasive grains easily come into contact with the silicon-germanium film, and the polishing speed of silicon germanium is improved.

Furthermore, when the polishing composition contains an inorganic salt, the electrical conductivity of the polishing composition is increased. As a result, it is considered that an electric double layer formed on the surface of the silicon-germanium film is compressed, the action of the abrasive grains is improved, and the polishing speed of the silicon-germanium film is increased.

Embodiments according to one aspect of the present invention are described hereinbelow. The present invention is not limited only to the following embodiments.

As used herein, the expression “X to Y” showing a range represents “X or more and Y or less”. Further, unless otherwise indicated, operations and measurements of physical properties and the like are carried out under conditions of room temperature (of 20 to 25° C.) and relative humidity of 40 to 50% RH.

<Polishing Composition>

[Abrasive Grains]

The polishing composition of the present aspect contains abrasive grains in which the number of silanol groups per unit surface area is more than 0/nm² and 2.0/nm² or less. The abrasive grains have an action of mechanically polishing an object to be polished, and improve the polishing speed of the object to be polished by the polishing composition.

The abrasive grains according to the present aspect are not particularly limited as long as the number of silanol groups per unit surface area (simply referred to as “silanol group density” in the present specification) of the abrasive grains is more than 0/nm² and 2.0/nm² or less. When the silanol group density of the abrasive grains is within such a range, the polishing speed of silicon germanium can be sufficiently increased. The silanol group density of the abrasive grains is preferably 0.5/nm² or more and 2.0/nm² or less, and more preferably 1.0/nm² or more and 2.0/nm² or less.

The number of silanol groups per unit surface area of the abrasive grains can be calculated by the Sears method using neutralization titration described in Analytical Chemistry, vol. 28, No. 12, 1956, 1982 to 1983 by G. W. Sears. The calculation formula for the number of silanol groups is calculated by the following equation.

$$ρ = \frac{( c \times a \times {N}_{A} )}{( c \times s )} \qquad [ Equation 1 ]$$

ρ: Number of silanol groups [count/nm²]
c: Concentration of sodium hydroxide solution used in titration [mol/L]
a: Dropping amount of sodium hydroxide solution (pH 4-9) [ml]
N_{A}: Avogadro's number (6.022×10²³ [count/mol])
C: Mass of silica [g]
S: BET specific surface area [nm²/g]

The number of silanol groups per unit surface area of the abrasive grains can be controlled by selection of the method for producing abrasive grains, or the like.

The abrasive grains preferably include silica, more preferably include fumed silica or colloidal silica, and still more preferably include colloidal silica.

The shape of the abrasive grains is not particularly limited, and may be spherical or non-spherical. Specific examples of the non-spherical shape include various shapes such as a polygonal prism shape such as a triangular prism or a quadrangular prism; a cylindrical shape; a straw bag shape in which the central portion of a cylinder is inflated compared to edges; a doughnut shape in which the central portion of a disk is penetrated through, a plate shape, a so-called cocoon shape having a constriction at the central portion, a so-called associated type spherical shape in which a plurality of particles is integrated, a so-called kompeito shape having a plurality of protrusions on the surface thereof, and a rugby ball shape, and the non-spherical shape is not particularly limited.

When colloidal silica is used as the abrasive grains, the surface of the colloidal silica may be surface-modified with a silane coupling agent or the like.

Examples of the method for surface-modifying the surface of colloidal silica with a silane coupling agent include the following immobilization method. It is possible to perform the immobilization, for example, by the method described in “Sulfonic acid-functionalized silica through of thiol groups”, Chem. Commun. 246-247 (2003). Specifically, it is possible to obtain colloidal silica having sulfonic acid immobilized on the surface by coupling a silane coupling agent having a thiol group such as 3-mercaptopropyltrimethoxysilane to colloidal silica and then oxidizing the thiol group with hydrogen peroxide.

Alternatively, it is possible to perform the immobilization, for example, by the method described in “Novel Silane Coupling Agents Containing a Photolabile 2-Nitrobenzyl Ester for Introduction of a Carboxy Group on the Surface of Silica Gel” Chemistry Letters, 3, 228-229 (2000). Specifically, it is possible to obtain colloidal silica having carboxylic acid immobilized on the surface by coupling a silane coupling agent containing a photoreactive 2-nitrobenzyl ester to colloidal silica and then irradiating with light.

The above-described colloidal silica is colloidal silica having an anionic group (anionically modified colloidal silica), but colloidal silica having a cationic group (cationically modified colloidal silica) may be used. Examples of the colloidal silica having a cationic group include colloidal silica in which an amino group is immobilized on the surface. Examples of the method for producing such colloidal silica having a cationic group include a method for immobilizing a silane coupling agent having an amino group such as aminoethyltrimethoxysilane, aminopropyltrimethoxysilane, aminoethyltriethoxysilane, aminopropyltriethoxysilane, aminopropyldimethylethoxysilane, aminopropylmethyldiethoxysilane, or aminobutyltriethoxysilane on the surface of colloidal silica, as described in JP 2005-162533 A. As a result of this method, it is possible to obtain the colloidal silica having an amino group immobilized on the surface.

A lower limit of an average primary particle size of the abrasive grains is preferably 5 nm or more, more preferably 10 nm or more, and still more preferably 15 nm or more. As the average primary particle size of the abrasive grains increases, the polishing speed of the object to be polished by the polishing composition is improved. Further, the average primary particle size of the abrasive grains is preferably 120 nm or less, more preferably 80 nm or less, and still more preferably 50 nm or less. As the average primary particle size of the abrasive grains decreases, it becomes easier to obtain a surface with fewer defects by polishing using the polishing composition. The average primary particle size of the abrasive grains can be calculated, for example, on the assumption that the shape of the abrasive grains is a true sphere based on the specific surface area (SA) of the abrasive grains calculated from the BET method. In the present specification, as the average primary particle size of the abrasive grains, a value measured by the method described in Examples is adopted.

A lower limit of an average secondary particle size of the abrasive grains is preferably 30 nm or more, more preferably 40 nm or more, and still more preferably 50 nm or more. As the average secondary particle size of the abrasive grains increases, resistance during polishing decreases, and polishing can be stably performed. Further, the average secondary particle size of the abrasive grains is preferably 250 nm or less, more preferably 200 nm or less, still more preferably 150 nm or less, and particularly preferably 100 nm or less. As the average secondary particle size of the abrasive grains decreases, the surface area per unit mass of the abrasive grains increases, the contact frequency with the object to be polished is improved, and the polishing speed is further improved. Note that the average secondary particle size of the abrasive grains can be measured by, for example, a dynamic light scattering method represented by a laser diffraction scattering method. In the present specification, as the average secondary particle size of the abrasive grains, a value measured by the method described in Examples is adopted.

The upper limit of the aspect ratio of the abrasive grains is not particularly limited, and is preferably less than 2.0, more preferably 1.8 or less, and still more preferably 1.6 or less. Within such a range, defects on the surface of the object to be polished can be further reduced. The aspect ratio is an average of values obtained by taking the smallest rectangle circumscribing the image of the abrasive grain particles by a scanning electron microscope and dividing the length of the long side of the rectangle by the length of the short side of the same rectangle, and can be obtained using general image analysis software. The lower limit of the aspect ratio of the abrasive grains in the polishing composition is not particularly limited, and is preferably 1.0 or more.

In a particle size distribution of the abrasive grain, which is determined by the laser diffraction scattering method, the lower limit of D90/D10 which is a ratio of a particle diameter (D90) when the accumulated particle weight reaches 90% of total particle weight from the fine particle side to a particle diameter (D10) when the accumulated particle weight reaches 10% of total particle weight of all the particles is not particularly limited, and is preferably 1.1 or more, more preferably 1.2 or more, and still more preferably 1.3 or more. Further, in the particle size distribution of the abrasive grain in the polishing composition, which is determined by the laser diffraction scattering method, the upper limit of D90/D10 which is a ratio of a particle diameter (D90) when the accumulated particle weight reaches 90% of total particle weight from the fine particle side to a particle diameter (D10) when the particle weight reaches 10% of total particle weight from all the particles is not particularly limited, and is preferably 2.04 or less. Within such a range, defects on the surface of the object to be polished can be further reduced.

The size of the abrasive grain (average primary particle size, average secondary particle size, aspect ratio, D90/D10, and the like) can be appropriately controlled by the selection and the like of the method for producing the abrasive grains.

The content (concentration) of the abrasive grain in the polishing composition is not particularly limited, and is preferably 0.05% by mass or more, more preferably 0.1% by mass or more, and still more preferably 0.3% by mass or more relative to the total mass of the polishing composition. An upper limit of a content of the abrasive grains is preferably 20% by mass or less, more preferably 10% by mass or less, and still more preferably 5% by mass or less, relative to the total mass of the polishing composition. That is, the content of silica is preferably 0.05% by mass or more and 20% by mass or less, more preferably 0.1% by mass or more and 10% by mass or less, and still more preferably 0.3% by mass or more and 5% by mass or less, relative to the total mass of the polishing composition. Within such a range, the polishing speed of the object to be polished can be improved while costs are suppressed. Note that, in a case where the polishing composition contains two or more types of abrasive grains, the content of the abrasive grains is intended to be the total amount of these abrasive grains.

(Inorganic Salt)

The polishing composition of the present aspect contains an inorganic salt. Such an inorganic salt enhances the electrical conductivity of the polishing composition and compresses the electric double layer on the surface of silicon germanium. Therefore, the action of the abrasive grains on the surface of silicon germanium is improved, and the polishing speed of silicon germanium can be improved.

The inorganic salt is not particularly limited, and examples thereof include salts of monovalent inorganic acids, salts of divalent inorganic acids, and salts of trivalent inorganic acids.

Examples of the monovalent inorganic acids include hydrochloric acid, nitric acid, nitrous acid, and the like. Examples of the divalent inorganic acids include sulfuric acid, carbonic acid, sulfurous acid, thiosulfuric acid, phosphonic acid, and the like. Examples of the trivalent inorganic acids include phosphoric acid, phosphomolybdic acid, phosphotungstic acid, vanadic acid, and the like.

Examples of the salts of monovalent inorganic acids, the salts of divalent inorganic acids, and the salts of trivalent inorganic acids include lithium salts, sodium salts, potassium salts, calcium salts, magnesium salts, ammonium salts, and the like.

More specific examples of the inorganic salts include sodium nitrate, potassium nitrate, ammonium nitrate, magnesium nitrate, calcium nitrate, sodium nitrite, potassium nitrite, lithium carbonate, sodium carbonate, potassium carbonate, magnesium carbonate, calcium carbonate, lithium hydrogen carbonate, sodium hydrogen carbonate, potassium hydrogen carbonate, ammonium carbonate, sodium bicarbonate, sodium sulfate, potassium sulfate, ammonium sulfate, calcium sulfate, magnesium sulfate, sodium sulfite, potassium sulfite, calcium sulfite, magnesium sulfite, potassium thiosulfate, lithium sulfate, magnesium sulfate, sodium thiosulfate, sodium bisulfite, ammonium hydrogen sulfate, lithium hydrogen sulfate, sodium hydrogen sulfate, potassium hydrogen sulfate, trilithium phosphate, tripotassium phosphate, trisodium phosphate, triammonium phosphate, disodium hydrogen phosphate, dipotassium hydrogen phosphate, diammonium hydrogen phosphate, sodium dihydrogen phosphate, potassium dihydrogen phosphate, ammonium dihydrogen phosphate, and the like. These inorganic salts may be used singly or in combination of two or more kinds thereof.

Among these inorganic salts, from the viewpoint of preventing metal contamination of an object to be polished, a preferable inorganic salt is at least one selected from the group consisting of ammonium nitrate, ammonium sulfate, ammonium hydrogen sulfate, triammonium phosphate, diammonium hydrogen phosphate, and ammonium dihydrogen phosphate, a more preferable inorganic salt is selected from ammonium sulfate and triammonium phosphate, and a still more preferable inorganic salt is ammonium sulfate.

The content (concentration) of the inorganic salt in the polishing composition is not particularly limited, and is preferably 0.01% by mass or more, more preferably 0.02% by mass or more, and still more preferably 0.05% by mass or more, relative to the total mass of the polishing composition. Further, the upper limit of the content of the inorganic salt in the polishing composition used in the present invention is preferably 5% by mass or less, more preferably 3% by mass or less, and still more preferably 1% by mass or less, relative to the total mass of the polishing composition. When the content of the inorganic salt is 0.01% by mass or more, the electric double layer of the silicon-germanium film is sufficiently compressed, the abrasive grains easily come into contact with the silicon-germanium film, and thus the polishing speed of the silicon-germanium film can be increased. When the content of the inorganic salt is 5% by mass or less, an increase in the electrical conductivity can be suppressed, so that the abrasive grains and an electric double layer of a film other than silicon germanium (e.g., silicon oxide film or a silicon nitride film) are compressed, the abrasive grains are less likely to come into contact with the film other than silicon germanium. Thus, it is possible suppress an increase in the polishing speed of the film other than silicon germanium. Further, it is possible to suppress deterioration of storage stability due to increased electrical conductivity.

Note that in a case where the polishing composition contains two or more types of inorganic salts, the content of the inorganic salts is intended to be the total amount of these inorganic salts.

(Oxidizing Agent)

The polishing composition of the present aspect contains an oxidizing agent. The oxidizing agent has an action of oxidizing the surface of silicon germanium, and can further improve the polishing speed of silicon germanium by the polishing composition.

Examples of the oxidizing agent include hydrogen peroxide, sodium peroxide, barium peroxide, ozone water, silver (II) salt, iron (III) salt, permanganic acid, chromic acid, dichromic acid, peroxodisulfuric acid, peroxophosphoric acid, peroxosulfuric acid, peroxoboric acid, performic acid, peracetic acid, perbenzoic acid, perphthalic acid, hypochlorous acid, hypobromous acid, hypoiodous acid, chloric acid, chlorous acid, perchloric acid, bromic acid, iodic acid, periodic acid, persulfuric acid, dichloroisocyanuric acid, and salts thereof, and the like. These oxidizing agents may be used singly or in combination of two or more kinds thereof.

Among these oxidizing agents, an oxidizing agent containing no halogen atom is preferable, and hydrogen peroxide is more preferable.

A lower limit of the content (concentration) of the oxidizing agent in the polishing composition is preferably 0.001% by mass or more, and preferably 0.01% by mass or more. The lower limit is set in this manner, so that the polishing speed of silicon germanium can be further improved. An upper limit of the content of the oxidizing agent in the polishing composition is preferably 5% by mass or less, and more preferably 3% by mass or less. The upper limit is set in this manner, so that the material cost of the polishing composition can be reduced, and the load of the treatment of the polishing composition after use in polishing, that is, the load of the waste water treatment can also be reduced. In addition, the risk of excessive oxidation on the surface of an object to be polished by an oxidizing agent can also be reduced.

(Polishing Accelerator)

The polishing composition of the present aspect may further contain a polishing accelerator.

The polishing accelerator according to the present aspect has a function of adsorbing on a surface of a Ge oxide film and partially modifying the Ge oxide film. It is considered that the modified Ge oxide film is excellent in processability and the polishing speed increases, but dissolution hardly occurs and etching is suppressed.

Such a polishing accelerator preferably has an acid group. Examples of the acid group include a carboxy group, a phosphate group, a phosphonic acid group, a sulfuric acid group, a sulfonic acid group, and the like.

Specific examples of the polishing accelerator include ethylenediaminetetraacetic acid, nitrilotriacetic acid, hydroxyethylethylenediaminetriacetic acid, diethylenetriaminepentaacetic acid, triethylenetetramine hexaacetic acid, N-(2-hydroxyethyl)ethylenediamine-N,N′,N′-triacetic acid, glycol ether diamine tetraacetic acid, 1,3-propanediamine-N,N,N′,N′-tetraacetic acid, 1,3-diamino-2-propanol-N,N,N′,N′-tetraacetic acid, N-(2-hydroxyethyl)iminodiacetic acid, methyl acid phosphate, ethyl acid phosphate, ethyl glycol acid phosphate, isopropyl acid phosphate, phytic acid, 1-hydroxyethylidene-1,1-diphosphonic acid, aminotri(methylenephosphonic acid), diethylenetriaminepenta(methylenephosphonic acid), aminopoly(methylenephosphonic acid), 2-aminoethylphosphonic acid, nitrilotri(methylenephosphonic acid), N,N,N′,N′-ethylenediaminetetrakis(methylenephosphonic acid), diethylenetriamine penta(methylenephosphonic acid), ethane-1,1-diphosphonic acid, ethanehydroxy-1,1,2-triphosphonic acid, ethane-1-hydroxy-1,1-diphosphonic acid, ethane-1-hydroxy-1,1,2-triphosphonic acid, ethane-1,2-dicarboxy-1,2-diphosphonic acid, methanehydroxyphosphonic acid, 2-phosphonobutane-1,2-dicarboxylic acid, 2-phosphonobutane-1,2,4-tricarboxylic acid, α-methylphosphonosuccinic acid, N,N-di(2-hydroxyethyl)glycine, aspartic acid, glutamic acid, dicarboxymethylglutamic acid, (S,S)-ethylenediamine-N,N′-disuccinic acid, 2,3-dihydroxybenzoic acid, iminodiacetic acid, etidronic acid, mugineic acid, and salts thereof, and the like.

The polishing accelerators may be used singly or in combination of two or more kinds thereof. Further, the polishing accelerators may be synthetic products or commercially available products. Examples of the commercially available products of the polishing accelerators include CHELEST PH-430, CHELEST PH-540, CHELEST GA, CHELEST EDDS-4H, CHELEST HA (all described above are manufactured by CHELEST CORPORATION), and the like.

Among these polishing accelerators, a preferable polishing accelerator is at least one selected from the group consisting of N-(2-hydroxyethyl)ethylenediamine-N,N′,N′-triacetic acid, N,N,N′,N′-ethylenediaminetetrakis(methylenephosphonic acid), 2-phosphonobutane-1,2,4-tricarboxylic acid, N,N-di(2-hydroxyethyl)glycine, aspartic acid, and (S,S)-ethylenediamine-N,N′-disuccinic acid, a more preferable polishing accelerator is selected from N,N,N′,N′-ethylenediaminetetrakis(methylenephosphonic acid) and 2-phosphonobutane-1,2,4-tricarboxylic acid, and a still more preferable polishing accelerator is N,N,N′,N′-ethylenediaminetetrakis(methylenephosphonic acid), from the viewpoint that the processing speed of silicon germanium can be independently improved without changing the processing speed of other film types such as a silicon oxide film and a silicon nitride film.

The content (concentration) of the polishing accelerator in the polishing composition is not particularly limited, and is preferably 0.01% by mass or more, more preferably 0.05% by mass or more, and still more preferably 0.08% by mass or more, relative to the total mass of the polishing composition. Further, the upper limit of the content of the polishing accelerator in the polishing composition is preferably 5% by mass or less, more preferably 3% by mass or less, and still more preferably 1% by mass or less, relative to the total mass of the polishing composition. Within such a range, the polishing speed of silicon germanium can be further improved.

In a case where the polishing composition contains two or more types of polishing accelerators, the content of the polishing accelerators is intended to be the total amount of these polishing accelerators.

(pH Adjusting Agent) The polishing composition of the present aspect can contain a pH adjusting agent in order to set the pH to 6.0 or more.

The pH adjusting agent is not particularly limited as long as it is a compound having a pH adjusting function, and a known compound can be used. Examples of the pH adjusting agent include acids, alkalies, and the like.

As the acids, either inorganic acids or organic acids may be used. The inorganic acids are not particularly limited, and examples thereof include sulfuric acid, nitric acid, boric acid, carbonic acid, hypophosphorous acid, phosphorus acid, phosphoric acid, and the like. The organic acid is not particularly limited, and examples thereof include carboxylic acids such as formic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, tartaric acid, citric acid, and lactic acid; methanesulfonic acid, ethanesulfonic acid, isethionic acid, and the like.

The alkalies are not particularly limited, and examples thereof include hydroxides of alkali metals such as potassium hydroxide; ammonia, quaternary ammonium salts such as tetramethylammonium and tetraethylammonium; amines such as ethylenediamine and piperazine; and the like. Among the alkalies, ammonia is more preferable.

The pH adjusting agents may be used singly or in combination of two or more kinds thereof.

The content of the pH adjusting agent is not particularly limited, and may be appropriately adjusted so that the pH of the polishing composition falls within a desired range.

[Dispersing Medium]

The polishing composition of the present aspect may contain a dispersing medium for dispersing each component. Examples of the dispersing medium, water; alcohols such as methanol, ethanol, and ethylene glycol; ketones such as acetone, and mixtures thereof, and the like. Among these dispersing media, water is preferable as the dispersing medium. According to a more preferred embodiment of the present invention, the dispersing medium contains water. According to a still more preferred embodiment of the present invention, the dispersing medium is substantially composed of water. The term “substantially” as described above is intended to mean that a dispersing medium other than water may be contained as long as the target effect of the present invention can be achieved, and more specifically, the dispersing medium is preferably composed of 90% by mass or more and 100% by mass or less of water and 0% by mass or more and 10% by mass or less of a dispersing medium other than water, and more preferably composed of 99% by mass or more and 100% by mass or less of water and 0% by mass or more and 1% by mass or less of a dispersing medium other than water. Most preferably, the dispersing medium is water.

From the viewpoint of suppressing the inhibition of the action of the components contained in the polishing composition, water not containing impurities as much as possible is preferable as the dispersing medium. Specifically, pure water, ultrapure water, or distilled water, which is obtained by removing impurity ions with an ion exchange resin and then removing foreign substances through a filter, is more preferable.

(Other Components)

The polishing composition of the present aspect may further contain other components such as a complexing agent, an antiseptic agent, and an antifungal agent, if necessary. The content of other components may be appropriately set according to the purpose of addition. Hereinbelow, the antiseptic agent and the antifungal agent as other components are described.

Examples of the antiseptic agent and the antifungal agent include isothiazoline-based antiseptic agents such as 2-methyl-4-isothiazolin-3-one, 5-chloro-2-methyl-4-isothiazolin-3-one, 1,2-benzisothiazolin-3 one, and 2-n-octyl-4 isothiazolin-3 one, paraoxybenzoic acid esters, orthophenylphenol; phenoxyethanol, and the like. These antiseptic agents and antifungal agents may be used singly or in mixture of two or more kinds thereof.

(pH of Polishing Composition)

The pH of the polishing composition of the present aspect is not particularly limited as long as it is 6.0 or more, and can be appropriately adjusted according to the combination of the abrasive grains, the inorganic salt, and the oxidizing agent to be used. The lower limit of the pH is preferably 7.0 or more, preferably 8.0 or more, and more preferably 9.0 or more. The upper limit of the pH is, for example, 13.0 or less, preferably 12.0 or less, and more preferably 11.0 or less. In a case where the pH is less than 6.0, the etching reaction of silicon germanium is deteriorated, and the polishing speed is significantly reduced. In a case where the pH is more than 13, it is not possible to maintain the stability of the polishing composition.

The pH of the polishing composition can be measured by a pH meter (manufactured by HORIBA, Ltd., model number: LAQUA).

(Method for Producing Polishing Composition)

The method for producing the polishing composition of the present aspect is not particularly limited. For example, the polishing composition can be obtained by stirring and mixing abrasive grains, an inorganic salt, an oxidizing agent, and if necessary, another additive in a dispersing medium (e.g., water). Details of each component are as described above. Therefore, the present invention provides a method for producing a polishing composition, the method including mixing abrasive grains, an inorganic salt, and an oxidizing agent.

The temperature at which respective components are mixed is not particularly limited, and is preferably 10° C. or more and 40° C. or less, and heating may be performed to increase the rate of dissolution. The mixing time is also not particularly limited as long as uniform mixing can be achieved.

(Usage)

The polishing composition of the present aspect is preferably used for polishing an object to be polished containing silicon germanium. The germanium content in silicon germanium as the object to be polished is preferably 10% by mass or more.

The object to be polished according to the present aspect may contain another silicon-containing material as long as it contains silicon germanium. Examples of the silicon-containing material include a simple silicon substance and a silicon compound. Further, examples of the simple silicon substance include single-crystal silicon, polycrystalline silicon (polysilicon, Poly-Si), amorphous silicon, and the like. Examples of the silicon compound include silicon nitride (SiN), silicon oxide (SiO₂), silicon carbide, and the like. As the silicon-containing material, a low dielectric constant material having a relative dielectric constant of 3 or less is also included.

Examples of the film containing silicon oxide include a TEOS (tetraethyl orthosilicate) type silicon oxide film (hereinafter, also simply referred to as “TEOS film”) produced using tetraethyl orthosilicate as a precursor, a HDP (high density plasma) film, a USG (undoped silicate glass) film, a PSG (phosphorus silicate glass) film, a BPSG (boron-phospho silicate glass) film, a RTO (rapid thermal oxidation) film, and the like.

[Polishing Method and Method for Manufacturing Semiconductor Substrate]

One aspect of the present invention is a polishing method including polishing an object to be polished using the above polishing composition.

In addition, one aspect of the present invention is a semiconductor substrate manufacturing method, including polishing a semiconductor substrate by the above-described polishing method.

In the polishing method of the present aspect, as the polishing machine, it is possible to use a general polishing machine to which a holder for holding a substrate having the object to be polished, and the like, a motor capable of changing the rotation speed, and the like are attached, and which has a polishing table to which a polishing pad (polishing cloth) can be attached.

As the polishing pad, a general non-woven fabric, polyurethane, a porous fluororesin, and the like can be used without particular limitation. The polishing pad is preferably subjected to grooving such that the polishing solution is accumulated.

Regarding the polishing conditions, for example, the speed of rotation of the polishing table is preferably 10 rpm (0.17 s⁻¹) or more and 500 rpm (8.3 s⁻¹) or less. The pressure (polishing pressure) applied to a substrate having an object to be polished is preferably 0.5 psi (3.4 kPa) or more and 10 psi (68.9 kPa) or less. The method for supplying the polishing composition to the polishing pad is not particularly limited, and for example, a method for continuously supplying the polishing composition by a pump or the like is employed. This supply amount is not limited, and it is preferable that the surface of the polishing pad is always covered with the polishing composition according to the present invention.

After completion of polishing, the substrate is washed under flowing water, and is dried by shaking off water droplets adhering on the substrate by a spin dryer or the like, and thereby a substrate having a layer including a metal is obtained.

The polishing composition used in the polishing method of the present aspect may be a one-liquid type composition or may be a multi-liquid type composition including a two-liquid type one. In addition, the polishing composition used in the polishing method of the present aspect may be prepared by diluting a stock solution of the polishing composition, for example, 10 times or more using a diluent such as water.

The polishing speed when silicon germanium is polished by the polishing method of the present aspect is preferably 280 Å/min or more, more preferably 300 Å/min or more, and still more preferably 400 Å/min or more. Further, the etching amount of silicon germanium when silicon germanium is polished by the polishing method of the present aspect is preferably 80 Å or less, and more preferably 60 Å or less. The polishing speed and the etching amount can be measured by the methods described in Examples.

The polishing method of the present embodiment can also be applied to an object to be polished containing another material together with silicon germanium. In that case, an effect that a ratio of the polishing speed of silicon germanium to the polishing speed of another material is sufficiently high (i.e., a selection ratio is sufficiently high) can be obtained. For example, when the other material is silicon nitride, a ratio of the polishing speed of silicon germanium to the polishing speed of silicon nitride ([polishing speed of silicon germanium]/[polishing speed of silicon nitride]) is preferably 15 or more, more preferably 20 or more, and still more preferably 25 or more. Further, when the other material is silicon oxide, a ratio of the polishing speed of silicon germanium to the polishing speed of silicon oxide ([polishing speed of silicon germanium]/[polishing speed of silicon oxide]) is preferably 10 or more, and more preferably 13 or more.

### EXAMPLES

The present invention is described in more detail with reference to the following Examples and Comparative Examples. However, the technical scope of the present invention is not limited to the following Examples. Note that, unless otherwise indicated, “%” and “parts” refer to “% by mass” and “parts by mass”, respectively. Further, in the following Examples, unless otherwise indicated, operations were carried out under conditions of at room temperature (of 20 to 25° C.) and relative humidity of 40 to 50% RH.

### Example 1

0.5% by mass of colloidal silica (average primary particle size: 29 nm, average secondary particle size: 61 nm, silanol group density: 1.50/nm², aspect ratio: 1.55) as abrasive grains, 0.1% by mass of ammonium sulfate as an inorganic salt, and 0.16% by mass of hydrogen peroxide as an oxidizing agent were added relative to the entire mass of the polishing composition. These components were stirred and mixed in pure water (mixing temperature: about 25° C., mixing time: about 10 min). The pH was adjusted to 10.4 using ammonia as a pH adjusting agent to prepare a polishing composition.

### Example 2

A polishing composition was prepared in a similar manner to Example 1 except that ammonium sulfate was changed to triammonium phosphate.

### Example 3

A polishing composition was prepared in a similar manner to Example 1 except that the content of colloidal silica was changed to 1.0% by mass.

### Example 4

A polishing composition was prepared in a similar manner to Example 1 except that the content of ammonium sulfate was changed to 0.2% by mass.

### Example 5

A polishing composition was prepared in a similar manner to Example 1 except that the pH was adjusted to 9.2.

### Example 6

A polishing composition was prepared in a similar manner to Example 1 except that the content of hydrogen peroxide was changed to 0.40% by mass.

### Example 7

0.5% by mass of colloidal silica (average primary particle size: 29 nm, average secondary particle size: 61 nm, silanol group density: 1.50/nm², aspect ratio: 1.55) as abrasive grains, 0.1% by mass of ammonium sulfate as an inorganic salt, 0.16% by mass of hydrogen peroxide as an oxidizing agent, and 0.1% by mass of N,N,N′,N′-ethylenediaminetetrakis(methylenephosphonic acid) (EDTMP) as a polishing accelerator were added relative to the entire mass of the polishing composition. These components were stirred and mixed in pure water (mixing temperature: about 25° C., mixing time: about 10 min). The pH was adjusted to 10.4 using ammonia as a pH adjusting agent to prepare a polishing composition.

### Example 8

0.5% by mass of colloidal silica (average primary particle size: 29 nm, average secondary particle size: 61 nm, silanol group density: 1.50/nm², aspect ratio: 1.55) as abrasive grains, 0.1% by mass of triammonium phosphate as an inorganic salt, 0.16% by mass of hydrogen peroxide as an oxidizing agent, and 0.1% by mass of 2-phosphonobutane-1,2,4-tricarboxylic acid (PBTC) as a polishing accelerator were added relative to the entire mass of the polishing composition. These components were stirred and mixed in pure water (mixing temperature: about 25° C., mixing time: about 10 min). The pH was adjusted to 9.2 using ammonia as a pH adjusting agent to prepare a polishing composition.

### Comparative Example 1

0.5% by mass of colloidal silica (average primary particle size: 34 nm, average secondary particle size: 70 nm, silanol group density: 5.71/nm², aspect ratio: 1.19) as abrasive grains and 0.16% by mass of hydrogen peroxide as an oxidizing agent were added relative to the entire polishing composition. These components were stirred and mixed in pure water (mixing temperature: about 25° C., mixing time: about 10 min). The pH was adjusted to 9.2 using ammonia as a pH adjusting agent to prepare a polishing composition.

### Comparative Example 2

0.5% by mass of colloidal silica (average primary particle size: 34 nm, average secondary particle size: 70 nm, silanol group density: 5.71/nm², aspect ratio: 1.19) as abrasive grains, 0.1% by mass of ammonium sulfate as an inorganic salt, and 0.16% by mass of hydrogen peroxide as an oxidizing agent were added relative to the entire mass of the polishing composition. These components were stirred and mixed in pure water (mixing temperature: about 25° C., mixing time: about 10 min). The pH was adjusted to 9.2 using ammonia as a pH adjusting agent to prepare a polishing composition.

### Comparative Example 3

A polishing composition was prepared in a similar manner to Comparative Example 2 except that the pH was adjusted to 10.4.

### Comparative Example 4

0.5% by mass of colloidal silica (average primary particle size: 34 nm, average secondary particle size: 70 nm, silanol group density: 5.71/nm², aspect ratio: 1.19) as abrasive grains, 0.1% by mass of potassium sulfate as an inorganic salt, and 0.16% by mass of hydrogen peroxide as an oxidizing agent were added relative to the entire mass of the polishing composition. These components were stirred and mixed in pure water (mixing temperature: about 25° C., mixing time: about 10 min). The pH was adjusted to 10.4 using potassium hydroxide as a pH adjusting agent to prepare a polishing composition.

### Comparative Example 5

0.5% by mass of colloidal silica (average primary particle size: 29 nm, average secondary particle size: 61 nm, silanol group density: 1.50/nm², aspect ratio: 1.55) as abrasive grains and 0.16% by mass of hydrogen peroxide as an oxidizing agent were added relative to the entire polishing composition. These components were stirred and mixed in pure water (mixing temperature: about 25° C., mixing time: about 10 min). The pH was adjusted to 10.4 using ammonia as a pH adjusting agent to prepare a polishing composition.

### Comparative Example 6

A polishing composition was prepared in a similar manner to Comparative Example 5 except that the content of colloidal silica was changed to 4.0% by mass.

[Measurement of pH of Polishing Composition]

The pH of the polishing composition (liquid temperature: 25° C.) was confirmed with a pH meter (manufactured by HORIBA, Ltd., model number: LAQUA).

[Measurement of Average Primary Particle Size and Average Secondary Particle Size]

The average primary particle size of the abrasive grains was calculated from the specific surface area of the abrasive grains according to the BET method measured using “Flow Sorb II 2300” manufactured by Micromeritics Instrument Corporation and the density of the abrasive grains.

The average secondary particle size of the abrasive grains was measured with a dynamic light scattering type particle size distribution meter, UPA-UTI 151, manufactured by Nikkiso Co., Ltd.

[Measurement of Silanol Group Density]

The number of silanol groups (silanol group density) per unit surface area of the abrasive grains was calculated by the Sears method using neutralization titration described in Analytical Chemistry, vol. 28, No. 12, 1956, 1982 to 1983 by G. W. Sears. The calculation formula of the number of silanol groups was calculated by the following equation.

$$ρ = \frac{( c \times a \times {N}_{A} )}{( c \times s )} \qquad [ Equation 2 ]$$

ρ: Number of silanol groups [count/nm²]
c: Concentration of sodium hydroxide solution used in titration [mol/L]
a: Dropping amount of sodium hydroxide solution (pH 4-9) [ml]
N_{A}: Avogadro's number (6.022×10²³ [count/mol])
C: Mass of silica [g]
S: BET specific surface area [nm²/g]

The composition of the polishing compositions prepared above is shown in Table 1.

TABLE 1

| | Polishing composition | | | | | | | | | | | |
|---|---|---|---|---|---|---|---|---|---|---|---|---|
| | Abrasive grain | | | | | | | | Polishing | | | |
| | Average | Average | Silanol | | Inorganic salt | | Oxidizing agent | | accelerator | | | |
| | primary | secondary | group | Concen- | | Concen- | | Concen- | | Concen- | pH | |
| | particle | particle | (density) | tration | | tration | | tration | | tration | adjusting | |
| | size | size | [count/ | [% by | | [% by | | [% by | | [% by | agent | |
| | [nm] | [nm] | nm²] | mass] | Kind | mass] | Kind | mass] | Kind | mass] | Kind | pH |
| Example 1 | 29 | 61 | 1.50 | 0.5 | Ammonium | 0.1 | Hydrogen | 0.16 | — | — | Ammonium | 10.4 |
| | | | | | sulfate | | peroxide | | | | | |
| Example 2 | 29 | 61 | 1.50 | 0.5 | Tri- | 0.1 | Hydrogen | 0.16 | — | — | Ammonium | 10.4 |
| | | | | | ammonium | | peroxide | | | | | |
| | | | | | phosphate | | | | | | | |
| Example 3 | 29 | 61 | 1.50 | 1.0 | Ammonium | 0.1 | Hydrogen | 0.16 | — | — | Ammonium | 10.4 |
| | | | | | sulfate | | peroxide | | | | | |
| Example 4 | 29 | 61 | 1.50 | 0.5 | Ammonium | 0.2 | Hydrogen | 0.16 | — | — | Ammonium | 10.4 |
| | | | | | sulfate | | peroxide | | | | | |
| Example 5 | 29 | 61 | 1.50 | 0.5 | Ammonium | 0.1 | Hydrogen | 0.16 | — | — | Ammonium | 9.2 |
| | | | | | sulfate | | peroxide | | | | | |
| Example 6 | 29 | 61 | 1.50 | 0.5 | Ammonium | 0.1 | Hydrogen | 0.40 | — | — | Ammonium | 10.4 |
| | | | | | sulfate | | peroxide | | | | | |
| Example 7 | 29 | 61 | 1.50 | 0.5 | Ammonium | 0.1 | Hydrogen | 0.16 | EDTMP | 0.1 | Ammonium | 10.4 |
| | | | | | sulfate | | peroxide | | | | | |
| Example 8 | 29 | 61 | 1.50 | 0.5 | Tri- | 0.1 | Hydrogen | 0.16 | PBTC | 0.1 | Ammonium | 9.2 |
| | | | | | ammonium | | peroxide | | | | | |
| Comparative | 34 | 70 | 5.71 | 0.5 | phosphate | — | Hydrogen | 0.16 | — | — | Ammonium | 9.2 |
| Example 1 | | | | | | | peroxide | | | | | |
| Comparative | 34 | 70 | 5.71 | 0.5 | Ammonium | 0.1 | Hydrogen | 0.16 | — | — | Ammonium | 9.2 |
| Example 2 | | | | | sulfate | | peroxide | | | | | |
| Comparative | 34 | 70 | 5.71 | 0.5 | Ammonium | 0.1 | Hydrogen | 0.16 | — | — | Ammonium | 10.4 |
| Example 3 | | | | | sulfate | | peroxide | | | | | |
| Comparative | 34 | 70 | 5.71 | 0.5 | Potassium | 0.1 | Hydrogen | 0.16 | — | — | Potassium | 10.4 |
| Example 4 | | | | | sulfate | | peroxide | | | | hydroxide | |
| Comparative | 29 | 61 | 1.50 | 0.5 | — | — | Hydrogen | 0.16 | — | — | Ammonium | 10.4 |
| Example 5 | | | | | | | peroxide | | | | | |
| Comparative | 29 | 61 | 1.50 | 4.0 | — | — | Hydrogen | 0.16 | — | — | Ammonium | 10.4 |
| Example 6 | | | | | | | peroxide | | | | | |

EDTMP: N,N,N′,N'-ethylenediaminetetrakis(methylenephosphonic acid)
PBTC: 2-phosphonobutane-1,2,4-tricarboxylic acid

[Polishing Speed]

The following wafers were prepared as objects to be polished:

Silicon germanium (SiGe) wafer:silicon wafer having a 1500-Å-thick silicon-germanium film (Si:Ge=50:50 mass ratio) formed thereon (300 mm, blanket wafer, manufactured by Advanced Materials Technology, INC.);

Silicon oxide (TEOS) wafer:silicon wafer having a 10,000-Å-thick silicon oxide film formed thereon (300 mm, blanket wafer, manufactured by Advantech Co., Ltd.); and Silicon nitride (SiN) wafer:silicon wafer having a 3500-Å-thick silicon nitride film formed thereon (300 mm, blanket wafer, manufactured by Advantech Co., Ltd.).

Regarding the silicon germanium wafer, the silicon oxide wafer, and the silicon nitride wafer, the polishing speed was determined when polishing was performed using the polishing compositions of Example 1 to 8 and Comparative Example 1 to 6 for a certain period of time under the polishing conditions shown in Table 2 below. 300-mm substrates of the silicon germanium wafer, the silicon oxide wafer, and the silicon nitride wafer were formed into coupons with a size of 60 mm×60 mm, and the coupons were used.

[Table 2]

### Table 2

(Polishing and polishing conditions)
Polishing machine: one-side CMP polisher model: EJ380IN (manufactured by Engis Japan Corporation)
Polishing pad: trade name: H804-CZM (manufactured by FUJIBO HOLDINGS, INC.)
Polishing pressure: 1.8 psi (1 psi=6894.76 Pa)
Platen (table) rotation speed: 93 rpm
Head (carrier) rotation speed: 50 rpm
Supply of polishing composition: constant flow
Supply amount of polishing composition: 100 mL/min
Polishing time: 60 sec

The polishing speed (polishing rate) was calculated using the following equation.

$$Polishing rate [ Å / min ] = \frac{( \begin{matrix}Film thickness before polishing [ Å ] - \\ Film thickness after polishing [ Å ]\end{matrix} )}{( Polishing time [ min ] )} \qquad [ Equation 3 ]$$

The film thicknesses of silicon oxide and silicon nitride were determined by a light interference type film thickness measurement apparatus; Lambda Ace VM-2030, manufactured by SCREEN Semiconductor Solutions Co., Ltd., and evaluated by dividing a difference in film thickness before and after polishing by the polishing time.

The film thickness of silicon germanium was determined by a scanning X-ray fluorescence spectrometer; ZSX Primus 400, manufactured by Rigaku Corporation, and evaluated by dividing a difference in film thickness before and after polishing by the polishing time.

The selection ratio of the polishing speed was determined by calculating the polishing speed of silicon germanium/the polishing speed of silicon oxide and the polishing speed of silicon germanium/the polishing speed of silicon nitride, respectively.

[Etching Amount]

A silicon germanium wafer (Si:Ge=50:50 mass ratio) having a size of 30 mm×30 mm was immersed for 1 hour at 43° C. in a polishing composition rotated at 300 rpm using a stirring bar, and the dissolved amount (etching amount) was calculated based on a difference in film thickness before and after immersion.

The evaluation results are shown in Table 3 below.

TABLE 3

| | Polishing | | | Selection ratio of | | Etching |
|---|---|---|---|---|---|---|
| | speed [Å/min] | | | polishing speed | | amount of |
| | SiGe | SiN | TEOS | SiGe/SiN | SiGe/TEOS | SiGe [Å] |
| Example 1 | 407 | 15 | 31 | 27.1 | 13.1 | 52 |
| Example 2 | 387 | 18 | 29 | 21.5 | 13.4 | 55 |
| Example 3 | 814 | 24 | 48 | 33.9 | 17.0 | 60 |
| Example 4 | 801 | 22 | 51 | 36.4 | 15.7 | 75 |
| Example 5 | 316 | 12 | 23 | 26.3 | 13.7 | 47 |
| Example 6 | 574 | 19 | 35 | 30.2 | 16.6 | 73 |
| Example 7 | 1020 | 27 | 43 | 37.8 | 23.7 | 20 |
| Example 8 | 613 | 12 | 32 | 51.1 | 19.2 | 24 |
| Comparative | 25 | 2 | 2 | 14.8 | 12.4 | 23 |
| Example 1 | | | | | | |
| Comparative | 155 | 5 | 5 | 29.1 | 31.0 | 23 |
| Example 2 | | | | | | |
| Comparative | 274 | 14 | 30 | 19.5 | 9.1 | 52 |
| Example 3 | | | | | | |
| Comparative | 164 | 15 | 32 | 11.0 | 5.1 | 52 |
| Example 4 | | | | | | |
| Comparative | 37 | 2 | 2 | 14.9 | 16.7 | 23 |
| Example 5 | | | | | | |
| Comparative | 232 | 63 | 74 | 3.7 | 3.1 | 25 |
| Example 6 | | | | | | |

As is apparent from Table 3 above, it is found that, in the polishing compositions of the Examples, silicon germanium is polished at a sufficiently high polishing speed as compared to the polishing compositions of the Comparative Examples. It can also be seen that the ratio (selection ratio) of the polishing speed of silicon germanium to the polishing speed of silicon oxide or silicon nitride is sufficiently high.

The present application is based on JP 2020-158993 filed on Sep. 23, 2020, the disclosure of which is incorporated herein by reference in its entirety.

What is claimed is:

1. A polishing method comprising polishing an object to be polished using a polishing composition,
wherein the polishing composition includes:
abrasive grains;
an inorganic salt; and
an oxidizing agent,
wherein the number of silanol groups per unit surface area of the abrasive grains is more than 0/nm² and 2.0/nm² or less, and
a pH of the polishing composition is 6.0 or more; and
wherein the object to be polished includes silicon germanium.

2. The polishing method according to claim 1, wherein the abrasive grains contain colloidal silica.

3. The polishing method according to claim 1, wherein the inorganic salt is at least one selected from the group consisting of ammonium nitrate, ammonium sulfate, ammonium hydrogen sulfate, triammonium phosphate, diammonium hydrogen phosphate, and ammonium dihydrogen phosphate.

4. The polishing method according to claim 1, wherein the inorganic salt is ammonium sulfate.

5. The polishing method according to claim 1, wherein the oxidizing agent is hydrogen peroxide.

6. The polishing method according to claim 1, wherein the oxidizing agent does not contain a halogen atom.

7. The polishing method according to claim 1, further comprising a polishing accelerator.

8. The polishing method according to claim 7, wherein the polishing accelerator is at least one selected from the group consisting of N-(2-hydroxyethyl)ethylenediamine-N,N′,N′-triacetic acid, N,N,N′,N′-ethylenediaminetetrakis(methylenephosphonic acid), 2-phosphonobutane-1,2,4-tricarboxylic acid, N,N-di(2-hydroxyethyl)glycine, aspartic acid, and (S,S)-ethylenediamine-N,N′-disuccinic acid.

9. The polishing method according to claim 1, wherein the object to be polished further contains at least one of silicon oxide and silicon nitride.

10. The polishing method according to claim 1, wherein the abrasive grains are colloidal silica, the inorganic salt is ammonium sulfate or triammonium phosphate, the oxidizing agent is hydrogen peroxide, and wherein the polishing composition further comprises ammonia as a pH adjusting agent.

11. The polishing method according to claim 1,
wherein the object to be polished further contains at least one of silicon oxide and silicon nitride; and
wherein the abrasive grains are colloidal silica, the inorganic salt is ammonium sulfate or triammonium phosphate, the oxidizing agent is hydrogen peroxide, and wherein the polishing composition further comprises ammonia as a pH adjusting agent.

12. The polishing method according to claim 1, wherein the polishing composition further comprises an antiseptic and antifungal agent.

13. The polishing method according to claim 11, wherein the antiseptic and antifungal agent is at least one selected from the group consisting of 2-methyl-4-isothiazolin-3-one, 5-chloro-2-methyl-4-isothiazolin-3-one, 1,2-benzisothiazolin-3 one, 2-n-octyl-4 isothiazolin-3 one, paraoxybenzoic acid esters, orthophenylphenol, and phenoxyethanol.

14. The polishing method according to claim 11, wherein the pH of the polishing composition is 8.0 or more and 11.0 or less.
